(19) United States
(12) Patent Application Publication
(10) Pub. No.: US 2016/0276994 A1
(43) Pub. Date: Sep. 22, 2016

(54) ACOUSTIC ADJUSTMENT DEVICE AND ACOUSTIC ADJUSTMENT METHOD

(71) Applicant: JVC KENWOOD Corporation, Yokohama-shi (JP)

(72) Inventors: Mikito Yagi, Yokohama-shi (JP); Kenichi Takahashi, Yokohama-shi (JP)

(21) Appl. No.: 15/169,885

(22) Filed: Jun. 1, 2016

Related U.S. Application Data
(63) Continuation of application No. PCT/JP2014/073100, filed on Sep. 2, 2014.

(30) Foreign Application Priority Data
Dec. 6, 2013 (JP) 2013-253653

(51) Int. Cl. H03G 9/18; H03G 5/02; H03G 5/16; H04R 3/04; H03G 3/30

(52) U.S. Cl. CPC H03G 9/18; H04R 3/04; H03G 3/3005; H03G 5/16; H03G 5/025

(57) ABSTRACT

An adjustment value non-interlocking unit adds an acoustic effect without being interlocked with a volume adjustment value to an audio signal and outputs the audio signal and an adjustment value interlocking unit adds an acoustic effect with an additional amount with being interlocked with the volume adjustment value to the audio signal to which the acoustic effect is added in the adjustment value non-interlocking unit. A difference detecting unit detects a difference between the audio signal that is input to the adjustment value non-interlocking unit and the audio signal that is output from the adjustment value non-interlocking unit and an additional amount correction unit sets the additional amount in the adjustment value interlocking unit according to the difference such that the additional amount of the acoustic effect that is added to the audio signal with being interlocked with the volume adjustment value in the adjustment value interlocking unit becomes equal to the additional amount according to the difference detected in the difference detecting unit.

### CROSS-REFERENCE TO RELATED APPLICATION(S)

This application is a continuation of PCT international application Ser. No. PCT/JP2014/073100 filed on Sep. 2, 2014 which designates the United States, incorporated herein by reference, and which claims the benefit of priority from Japanese Patent Application No. 2013-253653, filed on Dec. 6, 2013, also incorporated herein by reference.

### BACKGROUND OF THE INVENTION

1. Field of the Invention

The present invention relates to an acoustic adjustment device and an acoustic adjustment method.

2. Description of the Related Art

Nowadays, there is a known acoustic function (adjustment value interlocking function) that changes, in order for an operator to obtain an acoustic output with a desired sound volume, an additional amount of an acoustic effect that is added to an audio signal with being interlocked with a volume adjustment value that is adjusted by, for example, operating a volume button. As an adjustment value interlocking function, for example, a loudness function, an audibility correction function of road noise of an audio device mounted on a vehicle, and the like are known. Furthermore, the loudness function is a function that increases a sound volume in low-frequency and high-frequency of the audio signals according to volume adjustment values. These adjustment value interlocking functions are designed such that, in general, an amount of the acoustic effect is decreased when a volume adjustment value is large and an amount of the acoustic effect is increased when a volume adjustment value is small.

Japanese Laid-open Patent Publication No. 01-198818 discloses, as an example of being interlocked with the volume described above, a loudness function and the configuration thereof. Patent Document 1 discloses a technology that uses a loudness correction value obtained by taking into account the effect of road noise of a vehicle to reproduce sound intended by the sound manufacturer.

However, there is a problem in that, if the adjustment value interlocking function described above and another acoustic function (adjustment value non-interlocking function) in which an amount of acoustic effect to be added is not interlocked with the volume adjustment value are used in combination, it is difficult to obtain the acoustic effect of the adjustment value interlocking function that is intended at the time of design.

Although as an example, for example, an equalizer, which is one of the adjustment value non-interlocking functions, is a device that obtains an audio signal with a desired frequency characteristic by changing the sound volume of each frequency band of the original audio signal. Consequently, the overall sound volume of the audio signal obtained after the sound volume of each frequency band has been adjusted by the equalizer becomes a sound volume that is different from the sound volume adjusted by a volume adjustment value.

If this type of equalizer is used in combination with the loudness function that is one of the adjustment value interlocking functions, the acoustic effect by the loudness function for a sound volume of a current volume adjustment value is added to the audio signal the sound volume of which is changed to be different from the sound volume of the current volume adjustment value by the equalizer. Consequently, there is a problem in that an audio signal with the acoustic effect, that is different from the effect intended when the loudness function is designed, is produced.

Accordingly, the present invention provides an acoustic adjustment device and an acoustic adjustment method that can obtain optimum acoustic effect.

### SUMMARY OF THE INVENTION

### Solution to Problem

According to the present invention, there is provided an acoustic adjustment device comprising: an adjustment value non-interlocking unit that adds an acoustic effect to an audio signal without being interlocked with a volume adjustment value; an adjustment value interlocking unit that adds an acoustic effect with an additional amount with being interlocked with the volume adjustment value to the audio signal to which the acoustic effect is added in the adjustment value non-interlocking unit; a difference detecting unit that detects a difference between the audio signal that is input to the adjustment value non-interlocking unit and the audio signal that is output from the adjustment value non-interlocking unit; and an additional amount correction unit that sets the additional amount in the adjustment value interlocking unit according to the difference such that the additional amount of the acoustic effect that is added to the audio signal with being interlocked with the volume adjustment value in the adjustment value interlocking unit becomes equal to the additional amount according to the difference detected in the difference detecting unit.

### BRIEF DESCRIPTION OF THE DRAWINGS

FIG. 1 is a block diagram illustrating an acoustic adjustment device of a first embodiment according to the present invention;

FIG. 2 is a schematic diagram illustrating filter characteristics of a first filter and a second filter arranged in the acoustic adjustment device of the first embodiment;

FIG. 3 is a schematic diagram illustrating an example of a setting pattern of an equalizer arranged in the acoustic adjustment device of the first embodiment;

FIG. 4 is a schematic diagram illustrating an additional amount storing unit arranged in a loudness device in the acoustic adjustment device according of the first embodiment;

FIG. 5 is a schematic diagram illustrating a shift amount storing unit arranged in the loudness device in the acoustic adjustment device of the first embodiment;

FIG. 6 is a schematic diagram illustrating shift control of an acoustic effect additional amount performed by the loudness device in the acoustic adjustment device of the first embodiment;

FIG. 7 is a block diagram illustrating the acoustic adjustment device of a second embodiment according to the present invention; and

FIG. 8 is a schematic diagram illustrating the storage content of a shift amount storing unit in the acoustic adjustment device of the second embodiment.

### DETAILED DESCRIPTION OF THE PREFERRED EMBODIMENTS

Preferred embodiments of an acoustic adjustment device that uses the present invention will be described in detail below with reference to the accompanying drawings.

### First Embodiment

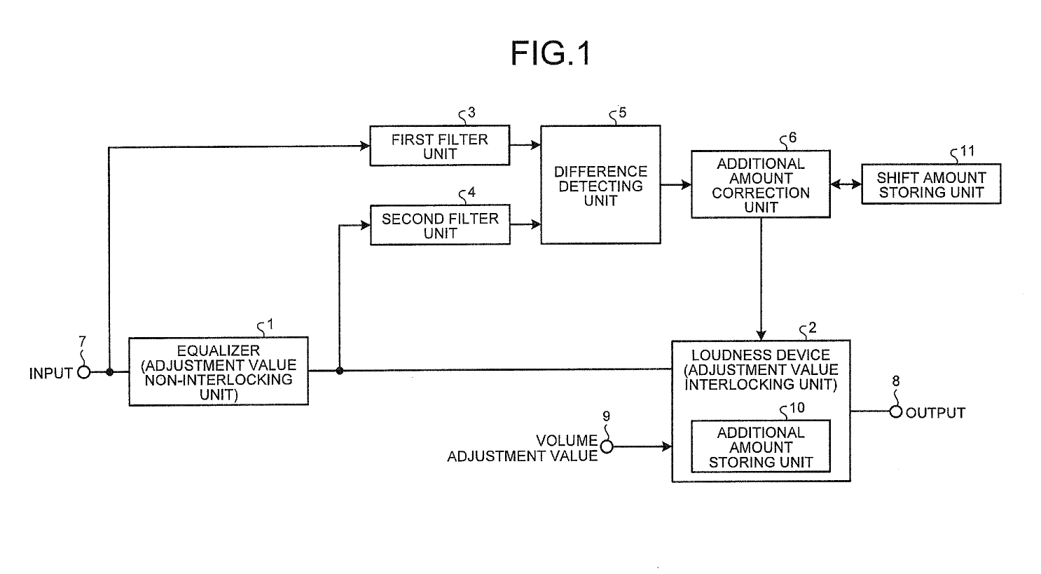

FIG. 1 is a block diagram illustrating an acoustic adjustment device of a first embodiment according to the present invention. As illustrated in FIG. 1, the acoustic adjustment device of the first embodiment includes an equalizer 1, a loudness device 2, a first filter unit 3, a second filter unit 4, a difference detecting unit 5, and an additional amount correction unit 6. The equalizer 1 is an example of an adjustment value non-interlocking unit. The loudness device 2 is an example of an adjustment value interlocking unit.

The equalizer 1 is an example of an adjustment non-interlocking function that adds an acoustic effect to an audio signal without being interlocked with the volume adjustment value that is set by, for example, an operator operating a volume adjustment button. Various devices are known as the adjustment non-interlocking function mentioned here; however, in the embodiment, as an example, a description will be given with the assumption that the adjustment non-interlocking function is the equalizer 1.

The loudness device 2 is an example of an adjustment interlocking function that adds the acoustic effect to an audio signal with being interlocked with the volume adjustment value that is set by, for example, an operator operating a volume adjustment button. Various devices are known as the adjustment interlocking function mentioned here; however, in the embodiment, as an example, a description will be given with the assumption that the adjustment interlocking function is the loudness device 2. Furthermore, the loudness device 2 is a function that increases a sound volume in low-frequency and high-frequency of the audio signals according to volume adjustment values. This type of the loudness device 2 is designed such that, an additional amount of the acoustic effect to be added to the audio signal is decreased when a volume adjustment value is large, whereas an additional amount of the acoustic effect to be added to the audio signal is increased when a volume adjustment value is small.

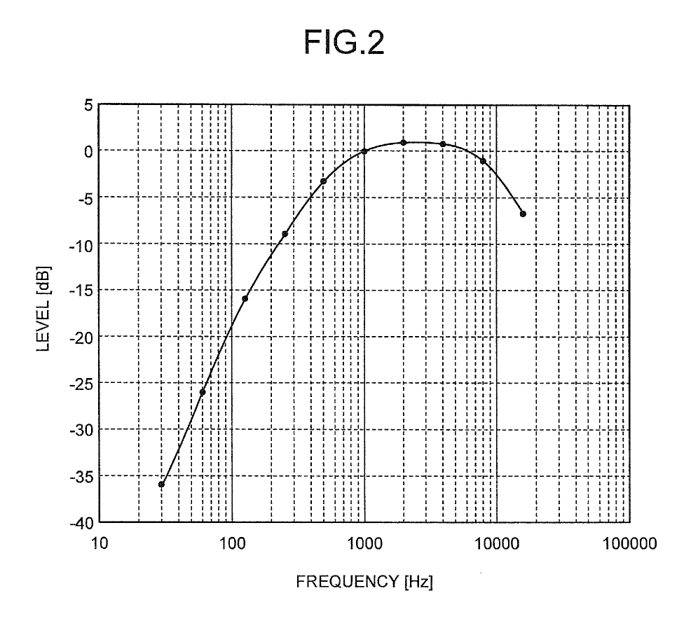

The first filter unit 3 and the second filter unit 4 performs, for example, a filtering process on an input audio signal with a filter characteristic of an audibility correction curve that is referred to as the so-called A-weighting curve. FIG. 2 illustrates the filter characteristics (frequency characteristics) of the first filter unit 3 and the second filter unit 4. The filter characteristics of the first filter unit 3 and the second filter unit 4 have the filter characteristics suited to the human audibility.

Namely, an audio signal with a low frequency equal to or less than 20 Hz and a high frequency equal to or greater than 5 kHz is hard to be audible to the human ear. Furthermore, an audio signal in a frequency range from about 2 kHz to 4 kHz is easily to be audible to the human ear. Each of the filter units 3 and 4 has the frequency characteristic considering the characteristic of the human audibility. Although as an example, as illustrated in FIG. 2, each of the filter units 3 and 4 is set to have the frequency characteristics of about +1 dB to 2 dB at the peak between the frequency of 2 kHz and 4 kHz, about −37 dB at the frequency of 30 Hz on the lower side, and about −7 dB at the frequency of 16 kHz on the higher side. By performing the filtering process on the input audio signal according to such frequency characteristics, each of the filter units 3 and 4 performs audibility correction so as to obtain the audio signal suited to the human audibility.

Furthermore, the first filter unit 3 and the second filter unit 4 do not need to be filters that have the characteristic of the A-weighting curve. For example, if the adjustment value interlocking function has a function of only changing the low frequency equal to or less than a predetermined frequency, a low path filter that passes the frequency equal to or less than the predetermined frequency may also be used. Furthermore, if the adjustment interlocking function equally detects signal in all frequency range, a band pass filter in all range may also be used or a filter does not need to be used.

In the following, an operation of the first embodiment having this configuration described above will be described. First, the audio signal supplied via the input terminal 7 illustrated in FIG. 1 is supplied to the equalizer 1 and the first filter unit 3. The equalizer 1 performs arithmetic processing for an infinite impulse response (IIR) filter by, for example, a digital signal processor (DSP) and adjusts the frequency characteristic of the input audio signal.

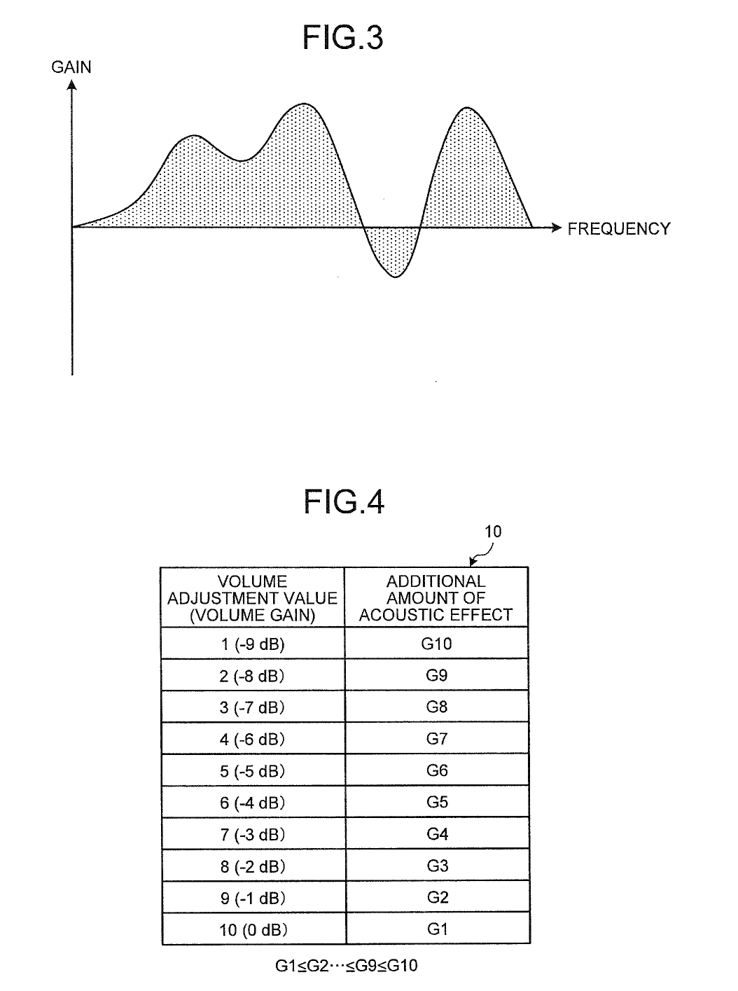

FIG. 3 illustrates an example of the signal waveform of the audio signal that has been subjected to the equalization process described above by the equalizer 1. The signal waveform of the audio signal that has been subjected to the equalization process varies according to each frequency characteristic that is adjusted by an operator. In other words, the equalizer 1 has a plurality of setting patterns for the respective frequency characteristics adjusted by the operator. The equalizer 1 converts the input audio signal to an audio signal with the frequency characteristics for the respective setting patterns.

Then, the audio signal that is output from the equalizer 1 is supplied to the loudness device 2. The loudness device 2 adds the acoustic effect with the additional amount according to the volume adjustment value that is adjusted by the operator operating the volume button to the audio signal supplied from the equalizer 1 and then outputs the audio signal via an output terminal 8. Specifically, an additional amount storing unit 10 illustrated in FIG. 1 is arranged in the loudness device 2.

FIG. 4 is a schematic diagram illustrating the additional amount storing unit 10. As illustrated in FIG. 4, the additional amount storing unit 10 stores therein, in an associated manner, each of the volume adjustment values and the additional amount of the acoustic effects added in the loudness device 2. The example illustrated in FIG. 4 is an example in which, by an operator operating a volume button, the volume can be adjusted in 10 stages, i.e., a volume 1 to a volume 10. In a case of the volume 1, the volume gain is, for example, −9 dB; in a case of the volume 5, the volume gain is, for example, −5 dB; and in a case of the volume 10, the volume gain is, for example, 0 dB. Furthermore, in a case of the volume 1, the additional amount of the acoustic effect added in the loudness device 2 is G10; in the case of the volume 5, the additional amount of the acoustic effect is, for example, G6; and in a case of the volume 10, the additional amount of the acoustic effect is, for example, G1. The relationship between each of the values of G1 to G10 that indicates the additional amount of the acoustic effects is represented by “G1≦G2 . . . G9≦G10”.

The volume adjustment value that is obtained by the operator adjusting the volume button is supplied to the loudness device 2 via an input terminal 9. By referring to the additional amount storing unit 10, the loudness device 2 detects the additional amount according to the volume adjustment value that is supplied via the input terminal 9. Then, the loudness device 2 adds the acoustic effect with the additional amount detected from the additional amount storing unit 10 to the audio signal received from the equalizer 1 and then outputs the audio signal via the output terminal 8. Specifically, the loudness device 2 adds a small amount of acoustic effect to the audio signal when the volume adjustment value is large and adds a large amount of acoustic effect to the audio signal when the volume adjustment value is small, whereby the loudness device 2 outputs the audio signal by reinforcing the low and high frequencies in which the degree of human audibility is poor.

At this point, the audio signal that is input to the equalizer 1 has the sound volume according to the volume adjustment value obtained by the operator adjusting the volume button. However, the audio signal that is input to the equalizer 1 is output after the frequency characteristic is adjusted. Consequently, the audio signal that is output from the equalizer 1 has a sound volume that is different from the sound volume of the audio signal that is input to the equalizer 1.

The loudness device 2 adds the acoustic effect with the additional amount according to the volume adjustment value that is obtained by the operator adjusting the volume button to the audio signal that is supplied from the equalizer 1. Consequently, the loudness device 2 may possibly add the acoustic effect with the additional amount according to the volume adjustment value to the audio signal obtained in the equalizer 1 with a sound volume not according to the volume adjustment value, and thus it may possibly be difficult to obtain an optimum effect according to the design intent of the loudness device 2.

The acoustic adjustment device of the first embodiment supplies, to the first filter unit 3, the audio signal that has not been input to the equalizer 1 and supplies, to the second filter unit 4, the audio signal that has been subjected to the equalization process in the equalizer 1. As described above with reference to FIG. 2, the first filter unit 3 and the second filter unit 4 perform the filtering process on the input audio signal by the filter characteristic with the audibility correction curve that is referred to as the so-called A-weighting curve. Consequently, the first filter unit 3 and the second filter unit 4 corrects, as audibility correction, the audio signal that has not been input to the equalizer 1 and the audio signal that has been output from the equalizer 1 to the audio signal suited to the human audibility and supplies the corrected audio signal to the difference detecting unit 5.

The difference detecting unit 5 detects a sound volume difference (ΔGEQ) between the audio signal that has been subjected to the audibility correction in the first filter unit 3 and that has not been input to the equalizer 1 and the audio signal that has been subjected to the audibility correction in the second filter unit 4 and that has been subjected to the equalization process in the equalizer 1. This sound volume difference (ΔGEQ) can be considered to be the same as an amount of change in an increase in the sound volume of the audio signal due to the equalization process performed by the equalizer 1. The additional amount correction unit 6 performs the correction such that the additional amount of the acoustic effect that is added to the audio signal in the loudness device 2 becomes to be the additional amount according to the sound volume difference (ΔGEQ) detected in the difference detecting unit 5.

Specifically, as illustrated in FIG. 1, a shift amount storing unit 11 is provided in the acoustic adjustment device of the embodiment. FIG. 5 is a schematic diagram illustrating the shift amount storing unit 11. As illustrated in FIG. 5, the shift amount storing unit 11 stores therein, in an associated manner, each of the sound volume differences (ΔGEQ) and the shift amount for each of the sound volume differences (ΔGEQ). The shift amount is information that instructs to change the additional amount of the acoustic effect that is added for the current volume adjustment value to the additional amount that is used for another volume adjustment value. In the example illustrated in FIG. 5, for example, if the sound volume difference (ΔGEQ) is 1 dB, the shift amount of the additional amount of the acoustic effect becomes “1”. If the shift amount is “1” and if the additional amount of the acoustic effect that is added for the current volume adjustment value is G2, the loudness device 2 performs shift control such that the additional amount of the acoustic effect that is added for the current volume adjustment value is shifted to G3. Similarly, if the shift amount is “3” and if the additional amount of the acoustic effect that is added for the current volume adjustment value is G4, the loudness device 2 performs shift control such that the additional amount of the acoustic effect that is added for the current volume adjustment value is shifted to G7. Furthermore, in this example, shift-up control of the additional amount is mainly described; however, if each of the sound volume differences (ΔGEQ) described above is a negative decibel, the loudness device 2 performs shift-down control on the additional amount of the acoustic effect that is added for the current volume adjustment value.

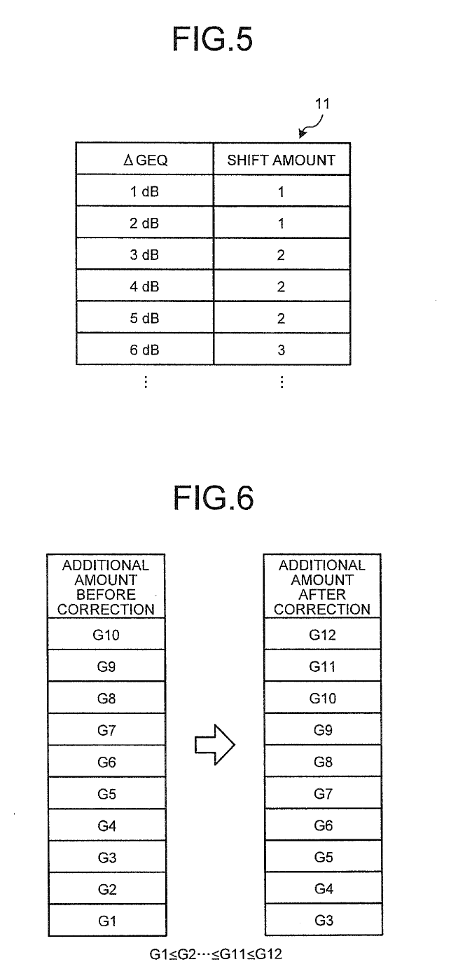

The additional amount correction unit 6 illustrated in FIG. 1 refers to the additional amount correction unit 6 by using the sound volume difference (ΔGEQ) detected in the difference detecting unit 5, whereby the additional amount correction unit 6 detects the shift amount described above and notifies the loudness device 2 of the detected shift amount. The loudness device 2 performs the shift control such that the additional amount of the acoustic effect that is added for the current volume adjustment value becomes to be the additional amount according to the notified shift amount. FIG. 6 indicates an example in which, because the sound volume difference (ΔGEQ) detected in the difference detecting unit 5 is, for example, 2 dB, the additional amount of the acoustic effect that is added for the current volume adjustment value is subjected to the shift control by “2”. Furthermore, the additional amount of Gil illustrated in FIG. 6 indicates the additional amount obtained when the volume adjustment value is “11” and the volume gain is “+1 dB”. Similarly, the additional amount of G12 indicates the additional amount obtained when the volume adjustment value is “12” and the volume gain is “+2 dB”.

As is clear from the description above, the acoustic adjustment device of the first embodiment detects the sound volume difference (ΔGEQ) between the audio signal that has not been subjected to the equalization process and the audio signal that has been subjected to the equalization process and corrects, by using the detected sound volume difference (ΔGEQ), the additional amount of the acoustic effect that is added for the current volume adjustment value in the loudness device 2. Consequently, even if the audio signal is adjusted to the sound volume that is different from the current volume adjustment value in the equalizer 1, it is possible to correct the additional amount of the acoustic effect added in the loudness device 2 to the additional amount for the sound volume adjusted in the equalizer 1.

Consequently, it is possible to obtain an optimum effect according to the design intent of the loudness device 2 even if the equalizer 1 that changes the sound volume of the audio signal without being interlocked with the volume adjustment value and the loudness device 2 that changes the acoustic effect to be added with being interlocked with the volume adjustment value are used in combination.

Furthermore, because each of the audio signal that has not been supplied to the equalizer 1 and the audio signal that has been supplied to the equalizer 1 is subjected to the audibility correction filtering process in the first filter unit 3 and the second filter unit 4, the difference detecting unit 5 can detect the audibility sound volume difference (ΔGEQ described above) between the audio signals before and after the supply to the equalizer 1. Then, the additional amount of the acoustic effect of the loudness device 2 can be corrected according to the audibility sound volume difference. Consequently, it is possible to correct the sound volume of the audibility.

### Second Embodiment

In the following, an acoustic adjustment device of a second embodiment according to the present invention will be described. The acoustic adjustment device of the second embodiment previously calculates the shift amount of the additional amount of the acoustic effect added in the loudness device 2 for each of the setting patterns of the equalizer 1 and stores the calculated shift amount in a shift amount storing unit. Then, the acoustic adjustment device detects the shift amount for the current setting pattern of the equalizer 1 from the shift amount storing unit and corrects the additional amount of the acoustic effect added in the loudness device 2. Furthermore, the first embodiment and the second embodiment only differ on this point. Thus, in below, only the difference will be described and descriptions of overlapped portions will be omitted.

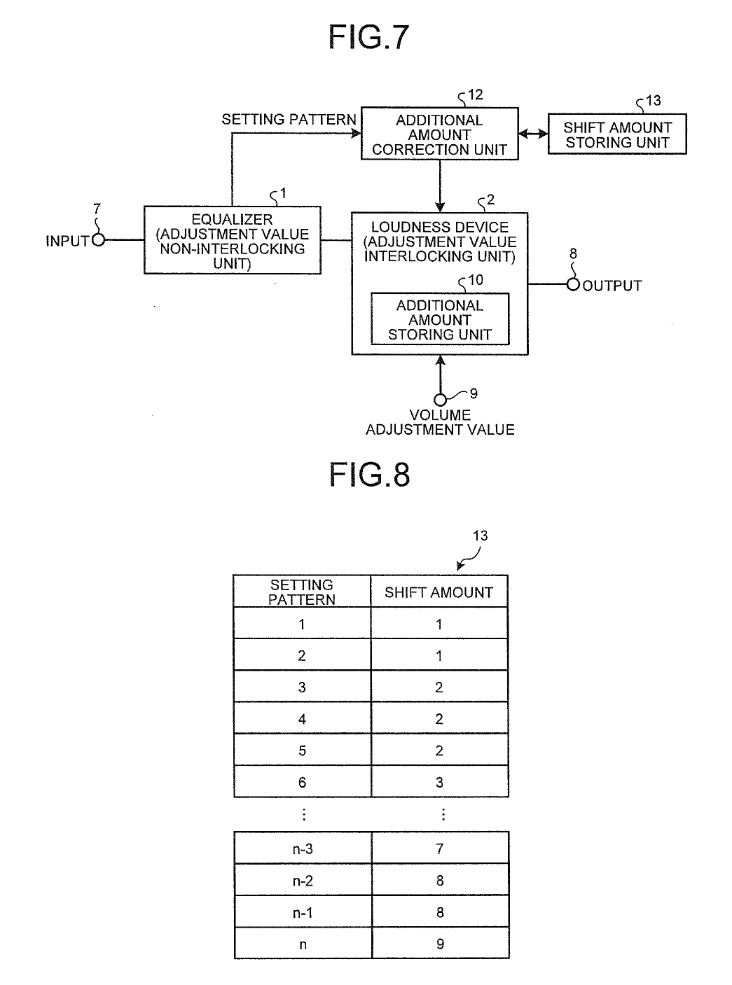

FIG. 7 illustrates a block diagram of the acoustic adjustment device of the second embodiment. The acoustic adjustment device of the second embodiment includes a shift amount storing unit 13 that stores therein, in an associated manner, each of the setting patterns of the equalizer 1 described with reference to FIG. 3 and the shift amount of the additional amount of the acoustic effect, which is added in the loudness device 2, for each of the setting patterns. Furthermore, the acoustic adjustment device of the second embodiment includes an additional amount correction unit 12 that detects the shift amount for the current setting pattern of the equalizer 1 from the shift amount storing unit 13 and that corrects the additional amount of the acoustic effect of the loudness device 2.

With the acoustic adjustment device according to the second embodiment, When, for example, an operator performs an operation of adjusting the audio signal to the signal with a desired frequency characteristic, information that indicates the current setting pattern is supplied to the additional amount correction unit 12 from the equalizer 1. The additional amount correction unit 12 refers to the shift amount storing unit 13 by using the information that indicates the current setting pattern, whereby the additional amount correction unit 12 detects the shift amount for the current setting pattern.

As the information that indicates the current setting pattern of the equalizer 1 supplied from the additional amount correction unit 12 to the shift amount storing unit 13, the information that indicates the sound volume in each frequency range may also be supplied from the equalizer 1 to the additional amount correction unit 12 as the information that indicates the setting pattern. Alternatively, the equalizer 1 may also detect the setting pattern for the adjustment operation performed by the operator and supply the information that indicates the detected setting pattern to the additional amount correction unit 12.

When the information that indicates the sound volume in each frequency range is supplied from the equalizer 1 to the additional amount correction unit 12 as the sound volume information that indicates the setting pattern, a pattern detection storing unit that stores therein the setting of the sound volume in each frequency range and the setting pattern number that is attached to each of the settings of the sound volume is provided in the additional amount correction unit 12 or outside the additional amount correction unit 12. The equalizer 1 supplies the information that indicates the sound volume in each frequency range to the additional amount correction unit 12. The additional amount correction unit 12 detects, from the pattern detection storing unit, the setting pattern of the sound volume in each frequency range that matches the information that indicates the sound volume in each frequency range supplied from the equalizer 1. Then, the additional amount correction unit 12 detects, from the pattern detection storing unit, the setting pattern number that is for the detected setting pattern of the sound volume in each frequency range.

In contrast, if the equalizer 1 detects the setting pattern for the adjustment operation performed by the operator and supplies the information that indicates the detected setting pattern to the additional amount correction unit 12, a pattern detection storing unit that stores therein the setting of the sound volume in each frequency range and the setting pattern number that is attached to each of the settings of the sound volume is provided in the equalizer 1 or outside the equalizer 1. In this case, the equalizer 1 detects, from the pattern detection storing unit, the setting pattern of the sound volume in each frequency range that matches the sound volume in each frequency range that has been adjusted by the operator by the operation. Then, the equalizer 1 detects, from the pattern detection storing unit, the setting pattern number that is for the detected setting pattern of the sound volume in each frequency range. The equalizer 1 supplies the setting pattern number that is detected from the pattern detection storing unit to the additional amount correction unit 12 as the information that indicates the setting pattern described above.

Furthermore, the setting patterns may also be managed by attaching different setting pattern numbers if the sound volumes slightly differ. Furthermore, in terms of audibility, a plurality of setting patterns with which the same acoustic effect can be obtained may be set as the same setting pattern and managed by attaching the same setting pattern number.

In the following, FIG. 8 indicates the content stored in the shift amount storing unit 13. The shift amount storing unit 13 stores therein, in an associated manner for each setting pattern, the associated shift amount indicating the additional amount of the acoustic effect added in the loudness device 2. For example, the shift amount of “1” that indicates that the shift amount is shifted up by one stage is associated with the setting pattern with the setting pattern number of “1”. Similarly, the shift amount of “3” that indicates that the shift amount is shifted up by three stages is associated with the setting pattern with the setting pattern number of “6”. Furthermore, the shift amount of “9” that indicates that the shift amount is shifted up by nine stages is associated with the setting pattern with the setting pattern number of “n (n is a natural number equal to or greater than 10)”.

The additional amount correction unit 12 refers to the shift amount storing unit 13 by using the setting pattern number that is detected from the pattern detection storing unit described above or the setting pattern number supplied from the equalizer 1. Then, the additional amount correction unit 12 detects the shift amount for the setting pattern number from the shift amount storing unit 13 and notifies the loudness device 2 of the detected shift amount. Furthermore, the example illustrated in FIG. 8 is an example among some of the setting patterns, in which the same shift amount is allocated to the setting patterns with which the same acoustic effect in terms of audibility can be obtained. In this example, the shift amount of “1” is allocated to the setting pattern with the setting pattern number of “1” and “2”. Similarly, the shift amount of “2” is allocated to the setting pattern with the setting pattern number of “3” to “5”.

As described with reference to FIG. 6, the loudness device 2 performs the shift control such that the additional amount of the acoustic effect added according to the current volume adjustment value becomes equal to the additional amount according to the notified shift amount. Consequently, even if the audio signal is adjusted to the sound volume that is different from the current volume adjustment value in the equalizer 1, it is possible to obtain the same effect obtained in the first embodiment described above, such as the additional amount of the acoustic effect added in the loudness device 2 being able to be corrected to the additional amount according to the sound volume adjusted in the equalizer 1.

Furthermore, in a case of the acoustic adjustment device of the second embodiment, implementation is possible with a simple configuration by only providing the shift amount storing unit 13 that is used to detect the shift amount for each of the setting patterns of the equalizer 1. Consequently, the implementation is possible with a simple circuit configuration and at a low cost.

Each of the embodiments has been described as an example and is not intended to limit the scope of the present invention. Indeed, the novel embodiments described herein may be embodied in a variety of other forms; furthermore, various omissions, substitutions, and changes in the form of the embodiment described herein may be made without departing from the spirit of the invention. For example, the adjustment value non-interlocking unit in the embodiments described above is the 1; however, a device other than the equalizer 1 may also be used if the device has a function of changing a sound volume of an audio signal. Even in this case, the same effect as that described above can be obtained. Each of the embodiments and a modification of each of the embodiments are included in the scope or the spirit of the invention and are included in the invention described in the accompanying claims and their equivalents.

According to the present invention, optimum acoustic effect can be obtained.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An acoustic adjustment device comprising:
an adjustment value non-interlocking unit that adds an acoustic effect to an audio signal without being interlocked with a volume adjustment value;
an adjustment value interlocking unit that adds an acoustic effect with an additional amount with being interlocked with the volume adjustment value to the audio signal to which the acoustic effect is added in the adjustment value non-interlocking unit;
a difference detecting unit that detects a difference between the audio signal that is input to the adjustment value non-interlocking unit and the audio signal that is output from the adjustment value non-interlocking unit; and
an additional amount correction unit that sets the additional amount in the adjustment value interlocking unit according to the difference such that the additional amount of the acoustic effect that is added to the audio signal with being interlocked with the volume adjustment value in the adjustment value interlocking unit becomes equal to the additional amount according to the difference detected in the difference detecting unit.

2. The acoustic adjustment device according to claim 1, further comprising:
a first filter unit that performs a filtering process with a filter characteristic of an audibility correction curve, on the audio signal that is input to the adjustment value non-interlocking unit, and
a second filter unit that performs a filtering process with a filter characteristic of an audibility correction curve, on the audio signal that is output from the adjustment value non-interlocking unit, wherein
the difference detecting unit detects, based on an audio signal output from the first filter unit and an audio signal output from the second filter unit, an audibility sound volume difference as the difference.

3. The acoustic adjustment device according to claim 1, further comprising;
a storing unit that stores therein, for each volume adjustment value and for each setting pattern in the adjustment value non-interlocking unit, a correction amount of the additional amount of the acoustic effect added in the adjustment value interlocking unit to the audio signal, the correction amount being created from an audibility sound volume difference that is obtained by detecting the difference between the audio signal obtained by performing the filtering process with the filter characteristic of the audibility correction curve on the audio signal which is input to the adjustment value non-interlocking unit and the audio signal obtained by performing the filtering process with the filter characteristic of the audibility correction curve on the audio signal which is output from the adjustment value non-interlocking unit, wherein
the additional amount correction unit detects, from the storing unit, the correction amount according to the volume adjustment value and for the setting pattern in the adjustment value non-interlocking unit and corrects the additional amount of the acoustic effect that is added to the audio signal with being interlocked with the volume adjustment value in the adjustment value interlocking unit, by the correction amount detected from the storing unit in the additional amount correction unit.

4. An acoustic adjustment method comprising:
a first adding step, performed in an adjustment value non-interlocking unit, of adding an acoustic effect to an audio signal without being interlocked with a volume adjustment value;
a second adding step, performed in an adjustment value interlocking unit, of adding an acoustic effect with an additional amount with being interlocked with the volume adjustment value to the audio signal to which the acoustic effect is added in the first adding step in the adjustment value non-interlocking unit;
a detecting step, performed in a difference detecting unit, of detecting a difference between the audio signal that is input to the adjustment value non-interlocking unit and the audio signal that is output from the adjustment value non-interlocking unit; and
a correcting step of correcting the additional amount of the acoustic effect that is added to the audio signal with being interlocked with the volume adjustment value in the second adding step to the additional amount according to the difference detected in the detecting step.
